(19) United States
(12) Patent Application Publication
(10) Pub. No.: US 2024/0090331 A1
(43) Pub. Date: Mar. 14, 2024

(54) THERMOELECTRIC CONVERSION MATERIAL, COMPOSITION FOR THERMOELECTRIC CONVERSION MATERIAL, THERMOELECTRIC CONVERSION ELEMENT, THERMOELECTRIC CONVERSION MODULE, AND METHOD OF MANUFACTURING THERMOELECTRIC CONVERSION MATERIAL

(71) Applicant: Panasonic Intellectual Property Management Co., Ltd., Osaka (JP)

(72) Inventors: TAKESHI KAWABE, Osaka (JP); YURIKO KANEKO, Nara (JP); TSUTOMU KANNO, Kyoto (JP); HIROMASA TAMAKI, Osaka (JP)

(21) Appl. No.: 18/515,329

(22) Filed: Nov. 21, 2023

Related U.S. Application Data
(63) Continuation of application No. PCT/JP2022/017563, filed on Apr. 12, 2022.

(30) Foreign Application Priority Data
Jun. 8, 2021 (JP) 2021-095573

(51) Int. Cl. H10N 10/853; H10N 10/01; H10N 10/855; H10N 19/00

(52) U.S. Cl. CPC H10N 10/853; H10N 10/01; H10N 10/855; H10N 19/00

(57) ABSTRACT

A thermoelectric conversion material of the present disclosure is a p-type thermoelectric conversion material which includes an alloy containing Mg and Bi as a main phase and which contains carbon. The thermoelectric conversion material includes, for example, a Mg₃(Sb,Bi)₂-based alloy as the main phase. An atomic percentage of Bi included in the main phase is greater than or equal to an atomic percentage of Sb included in the main phase. The thermoelectric conversion material satisfies, for example, 0.01 at %≤CC≤1.2 at %, where CC represents a content ratio of carbon in the thermoelectric conversion material.

### BACKGROUND

### 1. Technical Field

The present disclosure relates to a thermoelectric conversion material, a composition for a thermoelectric conversion material, a thermoelectric conversion element, a thermoelectric conversion module, and a method of manufacturing a thermoelectric conversion material.

### 2. Description of the Related Art

There have been known thermoelectric conversion materials. A thermoelectric conversion material is able to generate power based on a difference in temperature generated by inflow of thermal energy.

Japanese Unexamined Patent Application Publication No. 2019-207983 (Patent Document 1) discloses an n-type thermoelectric conversion material which includes a Mg₃(Sb,Bi)₂-based alloy as a main phase and contains carbon.

Japanese Unexamined Patent Application Publication No. 2020-80417 (Patent Document 2) discloses a thermoelectric conversion material which includes a polycrystalline magnesium silicide-based alloy as a main phase and contains carbon.

A. Bhardwaj et al., “Graphene boosts thermoelectric performance of a Zint1 phase compound”, RSC Advances, 2015, 5, 11058 (Non-patent Document 1) discloses a p-type thermoelectric conversion material which includes a Sb-rich Mg₃(Sb,Bi)₂-based alloy as a main phase and contains a graphene nanosheet.

### SUMMARY

One non-limiting and exemplary embodiment provides a novel thermoelectric conversion material.

The present disclosure provides a thermoelectric conversion material including:
an alloy containing Mg and Bi as a main phase; and
carbon, wherein
the thermoelectric conversion material is of p-type.

The present disclosure can provide a novel thermoelectric conversion material.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram of a La₂O₃-type crystal structure;

FIG. 2 is a diagram illustrating a Raman spectrum of a thermoelectric conversion material of the present disclosure;

FIG. 3 is a process chart illustrating an example of a method of manufacturing a thermoelectric conversion material of the present disclosure;

FIG. 4 is a schematic diagram illustrating an example of a thermoelectric conversion element and of a thermoelectric conversion module of the present disclosure;

FIG. 5 is an observation diagram of a thermoelectric conversion material fabricated in Example 1 after being subjected to a durability test;

FIG. 6 is an observation diagram of a thermoelectric conversion material fabricated in Comparative Example 1 after being subjected to the durability test;

FIG. 7 is an observation diagram of a thermoelectric conversion material fabricated in Comparative Example 2 after being subjected to the durability test; and

FIG. 8 is an observation diagram of a thermoelectric conversion material fabricated in Comparative Example 3 after being subjected to the durability test.

### DETAILED DESCRIPTIONS

### Underlying Knowledge Forming Basis of the Present Disclosure

An upper temperature limit of durability of a thermoelectric conversion material varies depending on the type, composition, and other factors of the material. Moreover, an operable temperature range of the thermoelectric conversion material is widened by raising the upper temperature limit of durability.

A thermoelectric conversion material including a Mg₃(Sb,Bi)₂-based alloy as a main phase has high thermoelectric conversion characteristics up to a temperature around 400° C. On the other hand, the thermoelectric conversion material including the Mg₃(Sb,Bi)₂-based alloy as the main phase is deteriorated due to decomposition of a compound therein when the temperature is higher than or equal to 527° C., and its thermoelectric conversion characteristics are therefore degraded.

In other words, the thermoelectric conversion material including the Mg₃(Sb,Bi)₂—based alloy as the main phase is preferably used at a temperature higher than or equal to 400° C. in order to realize the high thermoelectric conversion characteristics and is preferably used at a temperature lower than or equal to 520° C. to retain durability against the decomposition.

However, the present inventors have found out that the thermoelectric conversion material including the Mg₃(Sb,Bi)₂—based alloy as the main phase is decomposed at a temperature lower than 527° C. depending on an atomic percentage of Sb and an atomic percentage of Bi contained in the thermoelectric conversion material. To be more precise, the present inventors have found out that the thermoelectric conversion material including the Mg₃(Sb,Bi)₂—based alloy as the main phase is decomposed under a condition at 450° C. in the atmosphere when the atomic percentage of Bi is greater than or equal to the atomic percentage of the Sb.

Further investigations by the inventors have revealed that a product generated due to the decomposition is bismuth oxide. That is to say, the decomposition is thought to be attributable to an effect of oxidation, and ingenuity is therefore required to suppress the oxidation.

Patent Document 1 discloses the n-type thermoelectric conversion material which includes the Mg₃(Sb,Bi)₂—based alloy as the main phase and contains carbon. However, this document does not report a thermoelectric conversion material which includes a p-type Mg₃(Sb,Bi)₂—based alloy as a main phase and contains carbon.

Patent Document 2 discloses the thermoelectric conversion material which includes the polycrystalline magnesium silicide-based alloy as the main phase and contains carbon. Although Patent Document 2 discloses a possibility of obtaining a sintered body with a high density and at a high yield by causing the material to contain carbon. However, this document does not report the decomposition of the thermoelectric conversion material.

Non-patent Document 1 discloses the thermoelectric conversion material which includes, as the main phase, the p-type Sb-rich Mg₃(Sb,Bi)₂—based alloy containing the graphene nanosheet. To be more precise, Non-patent Document 1 discloses that a thermoelectric performance is improved by mixing carbon with a thermoelectric conversion material including a p-type Mg₃(Sb,Bi)₂—based alloy having a composition of Mg₃Sb₂₋ₓBiₓ(x≤0.2) as a main phase. Non-patent Document 1 does not report the p-type thermoelectric conversion material including the Mg₃(Sb,Bi)₂—based alloy in which the atomic percentage of Bi is greater than or equal to the atomic percentage of Sb. This document does not report the decomposition of the thermoelectric conversion material, either.

Based on these investigations, it is made clear that the p-type thermoelectric conversion material including the Mg₃(Sb,Bi)₂—based alloy as the main phase and containing carbon that is expected to cause a reduction action, in which the atomic percentage of Bi is greater than or equal to the atomic percentage of Sb, can suppress the decomposition. As a consequence, the p-type thermoelectric conversion material including the Mg₃(Sb,Bi)₂—based alloy as the main phase, in which the atomic percentage of Bi is greater than or equal to the atomic percentage of Sb, is obtained stably under a high-temperature condition higher than or equal to 400° C. and lower than or equal to 520° C., for instance.

### Embodiment of Present Disclosure

An embodiment of the present disclosure will be described below with reference to the drawings.

### Thermoelectric Conversion Material

A thermoelectric conversion material of the present disclosure is a thermoelectric conversion material that includes an alloy containing Mg and Bi as a main phase, and also contains carbon. The thermoelectric conversion material of the present disclosure is a p-type thermoelectric conversion material. For example, contents of Mg and Bi in the thermoelectric conversion material can be determined in accordance with X-ray diffraction (XRD), SEM-EDX that combines scanning electron microscopy (SEM) and energy-dispersive X-ray spectroscopy (EDX), and the like.

Note that the thermoelectric conversion material of the present disclosure only needs to be a thermoelectric conversion material that includes the alloy containing Mg and Bi as the main phase, which may also include a subphase formed from another alloy.

The thermoelectric conversion material further contains Sb, for example. The thermoelectric conversion material of the present disclosure is not limited to a specific composition, as long as the atomic percentage of Bi contained in the thermoelectric conversion material is greater than or equal to the atomic percentage of Sb contained in the thermoelectric conversion material.

The thermoelectric conversion material further contains at least one elemental species selected from the group consisting of Na, Li, and Ag, for example.

The thermoelectric conversion material of the present disclosure is the thermoelectric conversion material including a Mg₃(Sb,Bi)₂—based alloy as the main phase, for example. The thermoelectric conversion material of the present disclosure contains carbon and is a p-type thermoelectric conversion material. Moreover, the thermoelectric conversion material of the present disclosure is not limited to a specific composition, as long as the atomic percentage of Bi contained in the thermoelectric conversion material is greater than or equal to the atomic percentage of Sb contained in the thermoelectric conversion material. To be more precise, the thermoelectric conversion material of the present disclosure is not limited to a specific composition, as long as the atomic percentage of Bi contained in the Mg₃(Sb,Bi)₂—based alloy being the main phase is greater than or equal to the atomic percentage of Sb contained in the main phase. In other words, the thermoelectric conversion material of the present disclosure is a Bi-rich Mg₃(Sb,Bi)₂—based thermoelectric conversion material, for example.

When the thermoelectric conversion material is the thermoelectric conversion material including the Mg₃(Sb,Bi)₂—based alloy as the main phase, the thermoelectric conversion material may also include a subphase composed of another alloy.

The thermoelectric conversion material including the Mg₃(Sb,Bi)₂—based alloy as the main phase includes Mg₃(Sb,Bi)₂ and a material in which part of the elements in Mg₃(Sb,Bi)₂ is substituted by another element. When the thermoelectric conversion material including the Mg₃(Sb,Bi)₂—based alloy as the main phase includes the material in which part of the elements in Mg₃(Sb,Bi)₂ is substituted by another element, a content of such another element is less than the content of Mg and less than a sum of the content of Sb and the content of Bi on the basis of the amount of substance.

The Mg₃(Sb,Bi)₂—based thermoelectric conversion material of the present disclosure is preferably used at a temperature lower than or equal to 520° C. at which the material retains durability against decomposition.

A Mg₃(Sb,Bi)₂—based thermoelectric conversion material with the content of Sb greater than the content of Bi (in other words, rich in Sb) is expected to exert a high thermoelectric characteristic in a temperature range higher than or equal to 400° C.

Accordingly, an operating temperature range of the Sb-rich Mg₃(Sb,Bi)₂—based thermoelectric conversion material is preferably higher than or equal to 300° C. and lower than or equal to 520° C., more preferably higher than or equal to 350° C. and lower than or equal to 520° C., or even more preferably higher than or equal to 400° C. and lower than or equal to 520° C. In other words, an operating temperature range t1 of the Sb-rich Mg₃(Sb,Bi)₂—based thermoelectric conversion material preferably satisfies a condition of 300° C.≤t1≤520° C., more preferably satisfies a condition of 350° C.≤t1≤520° C., or even more preferably satisfies a condition of 400° C.≤t1≤520° C.

The Mg₃(Sb,Bi)₂—based thermoelectric conversion material of the present disclosure with the content of Bi greater than the content of Sb (in other words, rich in Bi) is expected to exert a high thermoelectric characteristic even in a temperature range lower than 400° C., for example. Accordingly, an operating temperature range of the Bi-rich Mg₃(Sb,Bi)₂—based thermoelectric conversion material is preferably higher than or equal to 200° C. and lower than or equal to 520° C., more preferably higher than or equal to 300° C. and lower than or equal to 520° C., or even more preferably higher than or equal to 300° C. and lower than or equal to 500° C. In other words, an operating temperature range t2 of the Bi-rich Mg₃(Sb,Bi)₂—based thermoelectric conversion material preferably satisfies a condition of 200° C.≤t2<520° C., more preferably satisfies a condition of 300° C.≤t2<520° C., or even more preferably satisfies a condition of 300° C.≤t2<500° C.

Accordingly, the Bi-rich Mg₃(Sb,Bi)₂—based thermoelectric conversion material of the present disclosure is suitable for cooling or power generation in the temperature range lower than 400° C. as compared with the Sb-rich Mg₃(Sb,Bi)₂—based thermoelectric conversion material.

A composition of the Mg₃(Sb,Bi)₂—based thermoelectric conversion material of the present disclosure is represented by formula (1) Mg₃₋ₘAₓSb_{2-z}Bi_{z}, for example.

A substance A in the formula (1) includes at least one elemental species selected from the group consisting of Na, Li, and Ag.

A value m in the formula (1) is preferably greater than or equal to −0.39 and less than or equal to 0.42, more preferably in a range from greater than or equal to −0.39 to less than or equal to 0.30, or even more preferably in a range from greater than or equal to −0.30 to less than or equal to 0.20. In other words, the value m preferably satisfies a mathematical formula−0.39≤m≤0.42, more preferably satisfies a mathematical formula−0.39≤m≤0.30, or even more preferably satisfies a mathematical formula−0.30≤m≤0.20.

A value x in the formula (1) is preferably greater than 0 and less than or equal to 0.12, more preferably greater than 0 and less than or equal to 0.10, or even more preferably greater than or equal to 0.001 and less than or equal to 0.05. In other words, the value x preferably satisfies a mathematical formula 0<x≤0.12, more preferably satisfies a mathematical formula 0<x≤0.10, or even more preferably satisfies a mathematical formula 0.001<x≤0.05.

A value z in the formula (1) is preferably greater than or equal to 1.0 and less than or equal to 2.0, more preferably greater than or equal to 1.0 and less than 2.0, or even more preferably greater than or equal to 1.0 and less than or equal to 1.9. In other words, the value z preferably satisfies a mathematical formula 1.0 K z K 2.0, more preferably satisfies a mathematical formula 1.0≤z<2.0, or even more preferably satisfies a mathematical formula 1.0≤z<1.9.

Since the thermoelectric conversion material has the above-described composition, the thermoelectric conversion material can be stably obtained without being decomposed even under the high-temperature condition being higher than or equal to 400° C. and lower than or equal to 520° C., for instance. Accordingly, the use of this thermoelectric conversion material is likely to increase yields of thermoelectric conversion elements and eventually to increase yields of thermoelectric conversion modules. In addition, it is easier to prevent decomposition of a sintered body including the thermoelectric conversion material when using such a thermoelectric conversion element and eventually using such a thermoelectric conversion module. As a consequence, durability of the thermoelectric conversion element and the thermoelectric conversion module is likely to be increased. The composition of the elements in the thermoelectric conversion material can be determined in accordance with the X-ray diffraction (XRD), the SEM-EDX that combines the scanning electron microscopy (SEM) and the energy-dispersive X-ray spectroscopy (EDX), and the like.

Due to preparatory reasons, an allowance of about 10% should be allowed for each element in a preparatory composition.

The thermoelectric conversion material of the present disclosure has a La₂O₃-type crystal structure, for example.

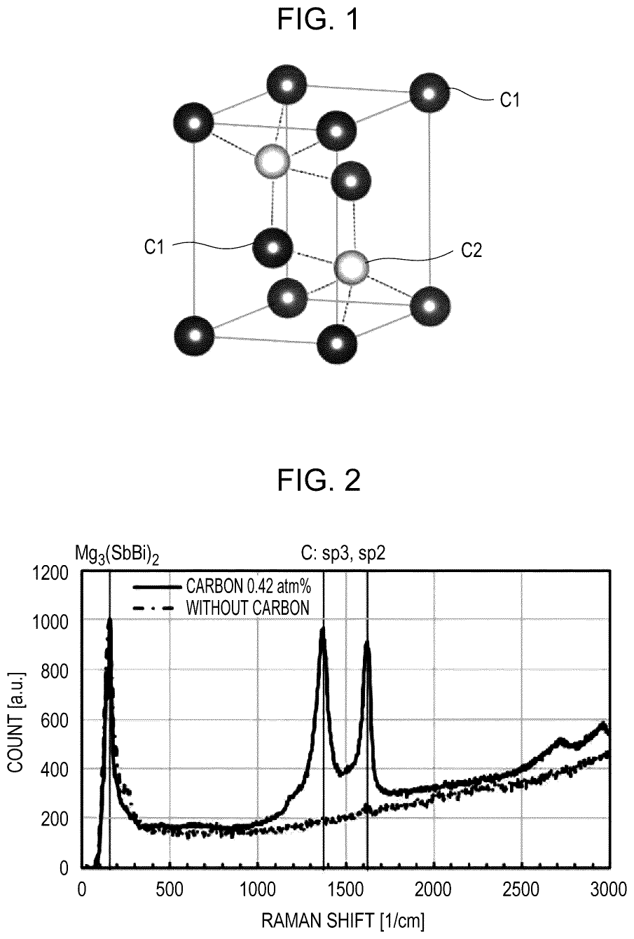

FIG. 1 is a schematic diagram of the La₂O₃-type crystal structure. The thermoelectric conversion material of the present disclosure may be a monocrystalline material or a polycrystalline material. The thermoelectric conversion material of the present disclosure is formed from multiple crystal grains, for example. Each of the crystal grains that constitute the thermoelectric conversion material has the La₂O₃-type crystal structure. The La₂O₃-type crystal structure in the thermoelectric conversion material of the present disclosure has been clarified by X-ray diffraction measurement. According to a result of the X-ray diffraction measurement, Mg is located at each C1 site and at least one of Sb or Bi is located at each C2 site, as illustrated in FIG. 1. The C1 sites and the C2 sites form bonds as indicated with dotted lines in FIG. 1.

### Identification of Contained Carbon

Carbon to be contained in the thermoelectric conversion material of the present disclosure is preferably a carbon material including at least one of allotropes such as graphene or graphite, or more preferably a carbon material containing graphite being the allotrope as a main component. For example, carbon is incorporated in the grains, at grain boundaries, and the like of the respective crystal grains constituting the thermoelectric conversion material of the present disclosure.

When the thermoelectric conversion material of the present disclosure includes the Mg₃(Sb,Bi)₂—based alloy as the main phase and the subphase formed from another alloy, carbon may be contained at a phase boundary between the main phase and the subphase. In other words, the thermoelectric conversion material of the present disclosure is the Bi-rich Mg₃(Sb,Bi)₂—based thermoelectric conversion material, for example.

Carbon contained in the thermoelectric conversion material of the present disclosure is preferably greater than or equal to 0.01 at % and less than or equal to 1.2 at %, more preferably greater than or equal to 0.1 at % and less than or equal to 1.0 at %, or even more preferably greater than or equal to 0.1 at % and less than or equal to 0.8 at %. In other words, the thermoelectric conversion material of the present disclosure preferably satisfies a mathematical formula 0.01 at %≤CC≤1.2 at %. Here, CC represents a content ratio of carbon in the thermoelectric conversion material of the present disclosure. The thermoelectric conversion material of the present disclosure more preferably satisfies a mathematical formula 0.10 at %≤CC≤1.0 at % or even more preferably satisfies a mathematical formula 0.10 at %≤CC≤0.8 at %.

That is to say, a mass ratio of the thermoelectric conversion material is preferably less than or equal to 100 relative to a mass ratio of carbon equal to 1. More preferably, a mass ratio between carbon and the thermoelectric conversion material is less than or equal to 1:80.

Carbon contained in the thermoelectric conversion material of the present disclosure is identified in accordance with the Raman spectroscopy. FIG. 2 is a diagram illustrating spectra representing a result of Raman spectroscopy of the thermoelectric conversion material of the present disclosure. A light source used in the Raman spectroscopy has a wavelength of 488 nm. According to the Raman spectroscopy, a peak near 180 (cm⁻¹) indicated in FIG. 2 is a peak representing the Mg₃(Sb,Bi)₂—based alloy. Meanwhile, two peaks near 1300 to 1650 (cm⁻¹) indicated in FIG. 2 are respective peaks representing carbon.

In FIG. 2, the thermoelectric conversion material of the present disclosure is plotted with a solid line (legend: solid line). As illustrated in FIG. 2, the thermoelectric conversion material of the present disclosure is determined to contain carbon when at least one of the two peak intensities of carbon is greater than or equal to 500 on the assumption that the peak intensity of the Mg₃(Sb,Bi)₂—based alloy is set to 1000. In other words, the thermoelectric conversion material of the present disclosure satisfies formula (M2) 0.5≤IC/IM. Here, IC represents the peak intensity of carbon in the Raman spectrum and IM represents the peak intensity of the Mg₃(Sb,Bi)₂—based alloy in the Raman spectrum.

A thermoelectric conversion material that does not contain carbon is plotted with a dotted line in FIG. 2 (legend: dotted line). Note that there may also be a case where a peak attributed to carbon is observed in the thermoelectric conversion material that does not contain carbon due to the use of a sintering die made of carbon. In this case, the peak intensity of carbon is indicated to be less than 500 on the assumption that the peak intensity of the Mg₃(Sb,Bi)₂—based alloy is set to 1000. In other words, the Mg₃(Sb,Bi)₂—based thermoelectric conversion material that does not contain carbon satisfies a mathematical formula (M3) 0.5>IC/IM.

Accordingly, it is possible to distinguish between the thermoelectric conversion material that does not contain carbon and the carbon-containing thermoelectric conversion material of the present disclosure.

### Manufacturing Method

A method of manufacturing a thermoelectric conversion material is not limited to a particular method. For example, the thermoelectric conversion material is manufactured in accordance with a manufacturing method which includes energizing alloy powder that contains Mg, Bi, and carbon in accordance with spark plasma sintering (SPS), and sintering the alloy powder at a temperature higher than or equal to 500° C. The thermoelectric conversion material includes the alloy containing Mg and Bi as the main phase, contains carbon, and is the p-type thermoelectric conversion material. To be more precise, the thermoelectric conversion material includes the Mg₃(Sb,Bi)₂—based alloy as the main phase, contains carbon, and is the p-type thermoelectric conversion material, for example. The alloy powder is polycrystalline powder, for instance. In the SPS, a die made of carbon is filled with the alloy powder, for example. A predetermined pressure is applied to the alloy power in the sintering process. The magnitude of the pressure is in a range from 10 MPa to 100 MPa, for instance. A sintering temperature of the alloy powder in the sintering process is, for example, below a melting temperature of the alloy, which is lower than or equal to 700° C., for example. An energization period of the alloy powder in the sintering process is not limited to a particular value. The sintering period is in a range from two minutes to one hour, for example.

The alloy powder is obtained in the form of a composition for the thermoelectric conversion material, for example.

The composition for the thermoelectric conversion material includes the alloy containing Mg and Bi, carbon, and at least one selected from the group consisting of Na, Li, and Ag. To be more precise, the composition for the thermoelectric conversion material includes the Mg₃(Sb,Bi)₂—based alloy, carbon, and at least one selected from the group consisting of Na, Li, and Ag, for example. The atomic percentage of Bi contained in the Mg₃(Sb,Bi)₂—based alloy is greater than or equal to the atomic percentage of Sb contained in the alloy.

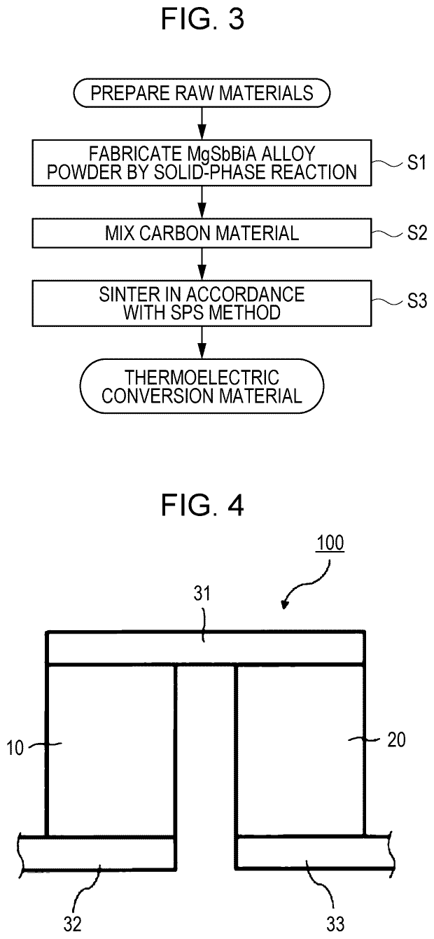

FIG. 3 is a process chart illustrating an example of the method of manufacturing the thermoelectric conversion material of the present disclosure.

FIG. 3 illustrates the example of the method of manufacturing the thermoelectric conversion material of the present disclosure in more detail. However, the method of manufacturing the thermoelectric conversion material of the present disclosure is not limited to the following example.

In step S1 of FIG. 3, a MgSbBiA alloy in the form of powder is obtained by a solid-phase reaction of Mg particles, Sb particles, Bi particles, which are raw materials, as well as powder of A being a doping material. A mechanical alloying method is an example of a solid-phase reaction method. Here, a different method such as a spark plasma sintering may be employed as the solid-phase reaction method.

Next, in step S2, the MgSbBiA alloy powder is mixed with carbon. The mechanical alloying method is an example of a mixing method. Here, a different method such as a ball mill method may be used as the mixing method.

Finally, in step S3, the precursor powder being the mixture of MgSbBiA and carbon is subjected to sintering, whereby a monocrystalline body or a polycrystalline body of MgSbBiA and carbon is obtained. A spark plasma sintering method or a hot press method can be employed for sintering, for example. The obtained sintered body may be directly used as the thermoelectric conversion material. Alternatively, the obtained sintered body may be subjected to a thermal treatment. In this case, the sintered body after the thermal treatment can be used as the thermoelectric conversion material as well. Composition analysis evaluation of sintered thermoelectric conversion material

It is possible to conduct composition analysis evaluation of the sintered thermoelectric conversion material. Examples of a method of this composition analysis evaluation include the energy-dispersive X-ray spectroscopy (hereinafter referred to as the “EDX”), X-ray photoelectron spectroscopy, and inductively coupled plasma atomic emission spectroscopy. These methods are also applicable to a manufactured thermoelectric conversion module. These methods are also applicable to the thermoelectric conversion element or the thermoelectric conversion module to be described later, which include the thermoelectric conversion material of the present disclosure.

An energy-dispersive X-ray spectroscope for SEM XFlash 6110 manufactured by Bruker Corporation is an example of an EDX device. A field-emission type SEM (FE-SEM) SU8220 manufactured by Hitachi High-Tech Corporation is an example of the SEM to be used in combination with the above-mentioned spectroscope.

### Thermoelectric Conversion Element

It is possible to provide a thermoelectric conversion element including the thermoelectric conversion material of the present disclosure. This thermoelectric conversion element can function as the p-type thermoelectric conversion element.

### Thermoelectric Conversion Module

It is possible to provide a thermoelectric conversion module which is formed by electrically connecting the p-type thermoelectric conversion element including the thermoelectric conversion material of the present disclosure to an n-type thermoelectric conversion element.

FIG. 4 is a schematic diagram illustrating an example of the thermoelectric conversion element and of the thermoelectric conversion module of the present disclosure. As illustrated in FIG. 4, a thermoelectric conversion module 100 includes a p-type thermoelectric conversion element 10, an n-type thermoelectric conversion element 20, a first electrode 31, a second electrode 32, and a third electrode 33, for example. The p-type thermoelectric conversion element 10 and the n-type thermoelectric conversion element 20 are electrically coupled in series. The first electrode 31 electrically couples a first end portion of the p-type thermoelectric conversion element 10 to a first end portion of the n-type thermoelectric conversion element 20. The second electrode 32 is electrically coupled to a second end portion of the p-type thermoelectric conversion element 10. The third electrode 33 is electrically coupled to a second end portion of the n-type thermoelectric conversion element 20.

The p-type thermoelectric conversion element 10 of the present disclosure includes the thermoelectric conversion material of the present disclosure.

The n-type thermoelectric conversion element 20 of the present disclosure includes the n-type thermoelectric conversion material including the Mg₃(Sb,Bi)₂—based alloy as the main phase, for example. In this instance, ratios of the numbers of atoms of Sb and Bi contained in the p-type thermoelectric conversion material and the n-type thermoelectric conversion material forming a pair in the thermoelectric conversion module 100 may be equal to or different from each other. When the ratios of the numbers of atoms are equal, a difference in amount of thermal expansion between the p-type thermoelectric conversion material and the n-type thermoelectric conversion material tends to be smaller. Accordingly, a thermal stress to be generated in the thermoelectric conversion module tends to be reduced.

Note that the n-type thermoelectric conversion element 20 in the present disclosure is not limited to the aforementioned configuration. The n-type thermoelectric conversion element may include a publicly known thermoelectric conversion material or may be a publicly known n-type thermoelectric conversion element.

Uses of thermoelectric conversion materials of the present disclosure are not limited. For example, thermoelectric conversion materials of the present disclosure are applicable in various uses including uses of thermoelectric conversion materials in the related art.

### Example 1

Fabrication of thermoelectric conversion material

A composition Mg_{2.99}Na_{0.01}Sb_{1.0}Bi_{1.0} in an amount of 4 g fabricated by a solid-phase reaction and carbon powder in an amount of 0.05 g (20 μm powder manufactured by Kojundo Chemical Lab. Co., Ltd.) were weighed inside a glove box. The inside of the glove box was controlled in an argon atmosphere up until the thermoelectric conversion material was obtained. Next, the respective materials thus weighed were sealed in a stainless steel container for mechanical alloying together with a stainless steel ball in the glove box. Thereafter, the materials were formed into mixed powder by using a normal temperature mill (Model: 8000D, manufactured by SPEX). Next, the mixed powder was put into a sintering space of a die made of carbon, and was subjected to powder compacting by using a punch made of carbon. The die was of the sintering type having a diameter of 10 mm.

Next, the die was placed in a chamber of a spark plasma sintering machine (Model: SPS515S, manufactured by Fuji Electronic Industrial Co., Ltd.). The chamber was controlled in an argon atmosphere. Next, an electric current was applied from the sintering machine to the die while applying a pressure of 50 MPa to the substance put in the die. As a consequence of application of the electric current, the temperature of the die reached 680° C. being a sintering temperature, and then this temperature was maintained for ten minutes. Thereafter, the heating was stopped by gradually reducing the electric current. After confirming that the temperature of the die was cooled down to room temperature, the sintered body was taken out of the die. A surface oxide layer constituting a surface of the sintered body that is the thermoelectric conversion material in contact with the sintering die was polished and then washed with acetone. The sintered body had a thickness of about 5 mm.

### Cutting Work on Thermoelectric Conversion Material

The fabricated sintered body being the thermoelectric conversion material was cut into a piece having dimensions of 3 mm×3 mm×5 mm. A worked surface of the thermoelectric conversion material after the cutting was polished and then washed with acetone. An electric resistance value of the thermoelectric conversion material was measured in accordance with a four-terminal measurement method by using a source measure unit manufactured by Keithley (Model number: 2400). As a result, the resistance value was 41 mΩ.

### Durability Test

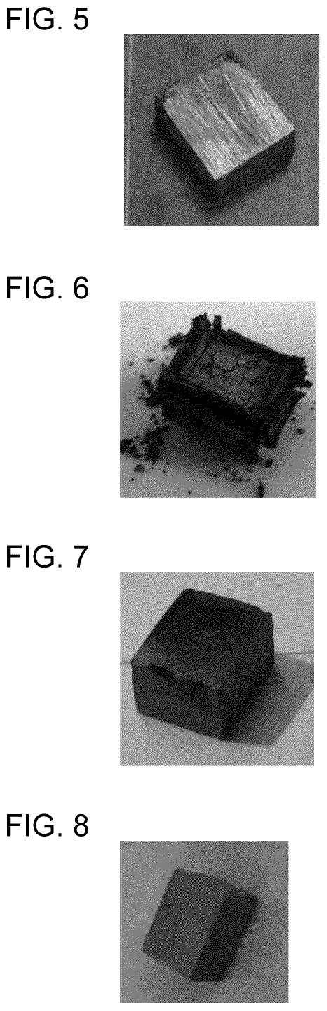

As a durability test, the thermoelectric conversion material was heated for two hours in the atmosphere at 450° C., which was close to an upper limit of the operating temperature of the thermoelectric conversion material. The surface was oxidized again due to the heating. Accordingly, the oxide layer was removed by polishing. FIG. 5 is an observation diagram of the thermoelectric conversion material fabricated in Example 1, which was subjected to surface polishing after the durability test. The electric resistance value was measured thereafter. As a result, the electric resistance value of the thermoelectric conversion material after the durability test was 40 mΩ. In other words, there was very little change in resistance between before and after the durability test.

### Comparative Example 1

### Fabrication of Thermoelectric Conversion Material

A thermoelectric conversion material was fabricated in a similar manner to Example 1 except that the composition Mg_{2.99}Na_{0.01}Sb_{1.0}Bi_{1.0} in the amount of 4 g fabricated in the solid-phase reaction was weighed inside the glove box.

### Cutting Work on Thermoelectric Conversion Material

The fabricated thermoelectric conversion material was cut into a piece having dimensions of 3 mm×3 mm×4 mm in a similar manner to Example 1. Then, the resistance was measured in a similar manner to Example 1. The resistance value was 30 mΩ.

### Durability Test

As a durability test, the thermoelectric conversion material was heated for two hours in the atmosphere at 450° C., which was close to the upper limit of the operating temperature of the thermoelectric conversion material in a similar manner to Example 1. As a consequence, the thermoelectric conversion material was decomposed. FIG. 6 is an observation diagram of the thermoelectric conversion material fabricated in Comparative Example 1 after the durability test. Specifically, the entire material turned into yellow and black powder as illustrated in FIG. 6, and the measurement of the resistance was impossible. As a consequence of X-ray spectroscopy of the yellow decomposed powder, a peak considered to represent bismuth oxide was observed.

### Comparative Example 2

### Fabrication of Thermoelectric Conversion Material

A thermoelectric conversion material was fabricated in a similar manner to Example 1 except that a composition Mg_{2.99}Na_{0.01}Sb_{1.25}Bi_{0.75} in the amount of 4 g fabricated in a solid-phase reaction was weighed inside the glove box.

### Cutting Work on Thermoelectric Conversion Material

The fabricated thermoelectric conversion material was cut into a piece having dimensions of 3 mm×3 mm×4 mm in a similar manner to Example 1 and Comparative Example 1. The electric resistance value was 37 mΩ.

### Durability Test

A durability test was carried out in a similar manner to Example 1 and Comparative Example 1. The thermoelectric conversion material was not decomposed. FIG. 7 is an observation diagram of the thermoelectric conversion material fabricated in Comparative Example 2 after the durability test. The electric resistance value of the thermoelectric conversion material after the durability test was 46 mΩ. In other words, the resistance was slightly increased after the durability test.

### Comparative Example 3

### Fabrication of Thermoelectric Conversion Material

A thermoelectric conversion material was fabricated in a similar manner to Example 1 except that a composition Mg_{2.99}Na_{0.0125}Sb_{0.5}Bi_{0.5} in the amount of 4 g fabricated in a solid-phase reaction was weighed inside the glove box.

### Cutting Work on Thermoelectric Conversion Material

The fabricated thermoelectric conversion material was cut into a piece having dimensions of 3 mm×3 mm×4 mm in a similar manner to Example 1, Comparative Example 1, and Comparative Example 2. The electric resistance value was 61 mΩ.

### Durability Test

A durability test was carried out in a similar manner to Example 1, Comparative Example 1, and Comparative Example 2. The thermoelectric conversion material was not decomposed. FIG. 8 is an observation diagram of the thermoelectric conversion material fabricated in Comparative Example 3 after the durability test. The electric resistance value of the thermoelectric conversion material after the durability test was 2997 mΩ. In other words, the resistance was markedly increased after the durability test.

### Summary of Example 1 and Comparative Examples 1 to 3

As shown in Example 1, the thermoelectric conversion material including the Mg₃(Sb,Bi)₂—based alloy as the main phase and containing carbon, in which the atomic percentage of Bi was greater than or equal to the atomic percentage of Sb was not decomposed after heating the thermoelectric conversion material in the atmosphere at 450° C. In other words, the thermoelectric conversion material including the Bi-rich Mg₃(Sb,Bi)₂—based alloy as the main phase and containing carbon was not decomposed after heating the thermoelectric conversion material in the atmosphere at 450° C. In addition, there was only a small change in electric resistance value between before and after the durability test.

On the other hand, as shown in Comparative Example 1, the thermoelectric conversion material including the Mg₃(Sb,Bi)₂—based alloy as the main phase, in which the atomic percentage of Bi was greater than or equal to the atomic percentage of Sb but no carbon was contained was decomposed when the thermoelectric conversion material was heated in the atmosphere at 450° C. In other words, the Bi-rich Mg₃(Sb,Bi)₂—based thermoelectric conversion material containing no carbon was decomposed when the thermoelectric conversion material was heated in the atmosphere at 450° C.

As shown in Comparative Example 2 and Comparative Example 3, the thermoelectric conversion material including the Mg₃(Sb,Bi)₂—based alloy as the main phase, in which the atomic percentage of Bi was less than the atomic percentage of Sb was not decomposed after the thermoelectric conversion material was heated in the atmosphere at 450° C. In other words, the thermoelectric conversion material including the Sb-rich Mg₃(Sb,Bi)₂—based alloy as the main phase but containing no carbon was not decomposed after heating the thermoelectric conversion material in the atmosphere at 450° C. In the meantime, the electric resistance value was increased after the durability test.

Thermoelectric conversion materials of the present disclosure are applicable to various uses including uses of a thermoelectric conversion material in the related art.

What is claimed is:

1. A thermoelectric conversion material comprising:
an alloy containing Mg and Bi as a main phase; and
carbon, wherein
the thermoelectric conversion material is a p-type thermoelectric conversion material.

2. The thermoelectric conversion material according to claim 1, further comprising Sb, wherein
an atomic percentage of Bi contained in the thermoelectric conversion material is greater than or equal to an atomic percentage of Sb contained in the thermoelectric conversion material.

3. The thermoelectric conversion material according to claim 1, further comprising at least one selected from the group consisting of Na, Li, and Ag.

4. The thermoelectric conversion material according to claim 1, wherein
the main phase is a Mg₃(Sb,Bi)₂—based alloy, and
an atomic percentage of Bi contained in the main phase is greater than or equal to an atomic percentage of Sb contained in the main phase.

5. The thermoelectric conversion material according to claim 4, wherein
the thermoelectric conversion material has a composition in which the main phase is represented by formula (1) Mg₃₋ₘAₓSb_{2-z}Bi_{z},
where
A includes at least one selected from the group consisting of Na, Li, and Ag,
−0.39≤m≤0.42,
0<x≤0.12, and
1.0≤z<2.0.

6. The thermoelectric conversion material according to claim 5, wherein
0.001≤x≤0.05.

7. The thermoelectric conversion material according to claim 4, wherein the thermoelectric conversion material satisfies formula (M2),
0.5<IC/IM formula (M2)
where IC represents a peak intensity of the carbon in a Raman spectrum, and
IM represents a peak intensity of the Mg₃(Sb,Bi)₂—based alloy in the Raman spectrum.

8. The thermoelectric conversion material according to claim 1, wherein
the thermoelectric conversion material satisfies formula (M1),
0.01 at %≤CC≤1.2 at % formula (M1)
where CC represents a content ratio of the carbon in the thermoelectric conversion material.

9. A composition for a thermoelectric conversion material, the composition comprising:
an alloy containing Mg and Bi;
carbon; and
at least one selected from the group consisting of Na, Li, and Ag.

10. A thermoelectric conversion element comprising the thermoelectric conversion material according to claim 1.

11. A thermoelectric conversion module comprising:
a p-type thermoelectric conversion element being the thermoelectric conversion element according to claim 10; and
an n-type thermoelectric conversion element electrically coupled to the p-type thermoelectric conversion element.

12. A method of manufacturing a thermoelectric conversion material, the method comprising:
energizing alloy powder that contains Mg, Bi, and carbon by spark plasma sintering; and
sintering the alloy powder at a temperature higher than or equal to 500° C.
